(19) United States
(12) Patent Application Publication
(10) Pub. No.: US 2007/0241333 A1
(43) Pub. Date: Oct. 18, 2007

(54) Amorphous silicon thin film transistor, organic light-emitting display device including the same and method thereof

(75) Inventors: Jae-Chul Park, Seoul (KR); Young-Soo Park, Suwon-si (KR); Young-Kwan Cha, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/703,255

(22) Filed: Feb. 7, 2007

(30) Foreign Application Priority Data
Apr. 17, 2006 (KR) 10-2006-0034673

(51) Int. Cl. H01L 31/00

(52) U.S. Cl. 257/61; 313/504; 257/E31.001

(57) ABSTRACT

An amorphous silicon thin film transistor, an organic light-emitting display (OLED) device including the same and method thereof are provided. The example amorphous silicon thin film transistor may include an amorphous silicon thin film transistor portion including a gate electrode, a gate insulating layer, an amorphous silicon layer, and source/drain electrodes and a heat generating portion generating heat and applying the heat to the amorphous silicon layer to reduce a threshold voltage of the amorphous silicon thin film transistor portion. The example method may include applying heat to an amorphous silicon layer if a threshold voltage of an amorphous silicon thin film transistor rises above a default level, the amorphous silicon thin film transistor including the amorphous silicon layer, the applied heat configured to reset the threshold voltage to the default level. The example OLED device may include a substrate and a plurality of pixels arranged in a matrix form on the substrate, each of the pixels comprising a switching transistor, a driving transistor, and an organic light-emitting diode.

### PRIORITY STATEMENT

This application claims the benefit of Korean Patent Application No. 10-2006-0034673, filed on Apr. 17, 2006, in the Korean Intellectual Property Office, the disclosure of which is incorporated herein in its entirety by reference.

### BACKGROUND OF THE INVENTION

1. Field of the Invention

Example embodiments of the present invention are generally related to an amorphous silicon thin film transistor, an organic light-emitting display (OLED) device including the same and method thereof, and more particularly related to an amorphous silicon thin film transistor, an organic light-emitting display (OLED) device including the same and method of resetting a threshold voltage of the amorphous silicon thin film transistor through heat application.

2. Description of the Related Art

Light-weight and low power liquid crystal display (LCD) devices may be an example of flat panel display (FPD) devices. However, because LCD devices may be passive display devices, there may be technical constraints in brightness, contrast, viewing angle and size of LCD devices.

An organic light-emitting display device may include organic light-emitting diodes (OLEDs) which are arranged two-dimensionally. Because organic light-emitting display devices may be self-emissive (e.g., as opposed to backlighting in LCD panels), organic light-emitting display devices may have an increased viewing angle and contrast, as compared to liquid crystal display devices. In addition, because an organic light-emitting display device may require no backlight, organic light-emitting display devices may be lighter, thinner and may consume less power than liquid crystal display devices. Also, as compared to LCD panels, an organic light-emitting display device may also have direct lower-voltage driving capability, higher response speed and robustness against external shocks, a broader temperature range and a lower manufacturing cost.

Driving an organic light-emitting display device based on an active matrix may include employing a transistor as a switching device in each pixel, such that the same luminance level may be obtained with a lower current (e.g., as compared to a conventional LCD panel). Thus, a lower power consumption, higher definition, and larger sized display device may be implemented.

As discussed above, an active matrix organic light-emitting display device may include a switching transistor and a transistor for driving an organic light-emitting diode. In such an organic light-emitting display device, a driving transistor for a back-bone of the organic light-emitting device may continuously operate for a relatively long time under a relatively high and continuous current. Accordingly, if an amorphous silicon thin film transistor (a-Si TFT) is used as the driving transistor, a threshold voltage thereof may increase over time, which may degrade a luminance of the organic light-emitting display device and may increase the rate of failure of the organic light-emitting display device.

### SUMMARY OF THE INVENTION

An example embodiment of the present invention is directed to an amorphous silicon thin film transistor, including an amorphous silicon thin film transistor portion including a gate electrode, a gate insulating layer, an amorphous silicon layer, and source/drain electrodes and a heat generating portion generating heat and applying the heat to the amorphous silicon layer to reduce a threshold voltage of the amorphous silicon thin film transistor portion.

Another example embodiment of the present invention is directed to an organic light-emitting display device including a substrate and a plurality of pixels arranged in a matrix form on the substrate, each of the pixels comprising a switching transistor, a driving transistor, and an organic light-emitting diode. In an example, the driving transistor may be embodied as a amorphous silicon thin film transistor including an amorphous silicon thin film transistor portion including a gate electrode, a gate insulating layer, an amorphous silicon layer, and source/drain electrodes and a heat generating portion generating heat and applying the heat to the amorphous silicon layer to reduce a threshold voltage of the amorphous silicon thin film transistor portion.

Another example embodiment of the present invention is directed to a method of reducing a threshold voltage, including applying heat to an amorphous silicon layer if a threshold voltage of an amorphous silicon thin film transistor rises above a default level, the amorphous silicon thin film transistor including the amorphous silicon layer, the applied heat configured to reset the threshold voltage to the default level.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a schematic cross-sectional view illustrating an amorphous silicon thin film transistor having a bottom-gate structure according to an example embodiment of the present invention.

FIG. 2 is a schematic cross-sectional view illustrating an amorphous silicon thin film transistor having a bottom-gate structure according to another example embodiment of the present invention.

FIG. 3 is a graph illustrating a change in a threshold voltage dependent on DC current/voltage stress and recovery of the threshold voltage in the amorphous silicon thin film transistors of FIGS. 1 and 2, respectively, according to another example embodiment of the present invention.

FIG. 4 is an equivalent circuit diagram illustrating a schematic structure of an organic light-emitting display device according to another example embodiment of the present invention.

FIG. 5 is a schematic cross-sectional view illustrating a major stacked structure of an organic light-emitting display device according to another example embodiment of the present invention.

FIG. 6 illustrates a layout of a major structure of one pixel in an organic light-emitting display device according to another example embodiment of the present invention.

FIG. 7 is a schematic cross-sectional view illustrating a major stacked structure of an organic light-emitting display device according to another example embodiment of the present invention.

FIG. 8 illustrates a layout of a major structure of one pixel in an organic light-emitting display device according to another example embodiment of the present invention.

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

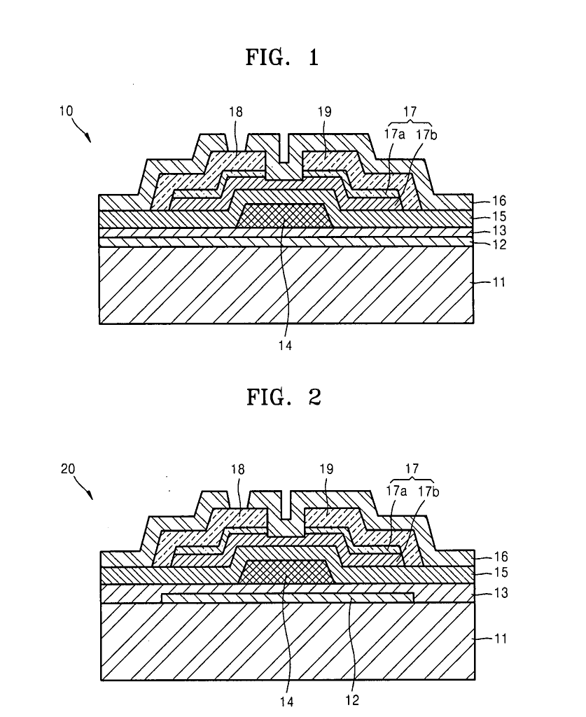

FIG. 1 is a schematic cross-sectional view illustrating an amorphous silicon thin film transistor 10 having a bottom-gate structure according to an example embodiment of the present invention.

FIG. 2 is a schematic cross-sectional view illustrating an amorphous silicon thin film transistor 20 having a bottom-gate structure according to another example embodiment of the present invention.

In the example embodiments of FIGS. 1 and 2, the amorphous silicon thin film transistors (a-Si TFT) 10 and 20 may each include an amorphous silicon thin film transistor portion having a gate electrode 14, a gate insulating layer 13, a gate insulating layer 15, an amorphous silicon layer 17, and source/drain electrodes 18 and 19, each formed on a substrate 11, and a heat generating portion 12 for applying heat to the amorphous silicon layer 17 to recover a threshold voltage. An example of the heat generating portion 12 may be a higher resistive layer and/or a lower power heating element which may be applied during fabricating processes. The amorphous silicon thin film transistors 10 and 20 may further include the insulating layer 13 positioned between the substrate 11 and an amorphous silicon thin film transistor structure. The heat generating portion 12 (e.g., a higher resistive layer, a heating element, etc.) may be formed at least in a region corresponding to the amorphous silicon layer 17 between the substrate 11 and the insulating layer 13. In an example, the substrate 11 may be embodied as a glass substrate or a plastic substrate.

In the example embodiments of FIGS. 1 and 2, the heat generating portion 12 (e.g., a higher resistive layer) may generate heat through Joule heating. For example, the higher resistive layer may include indium tin oxide (ITO) and/or indium zinc oxide (IZO). Alternatively, the heat generating portion 12 may include another material capable of effectively generating heat.

In the example embodiment of FIGS. 1 and 2, the heat generating portion 12 may be positioned on an entire surface of the substrate 11, as illustrated in the example embodiment of FIG. 1. Alternatively, the heat generating portion 12 may be patterned to be located locally in a region corresponding to (e.g., overlapping with) the amorphous silicon layer 17, as illustrated in the example embodiment of FIG. 2.

In the example embodiment of FIGS. 1 and 2, the insulating layer 13 may be formed so as to have higher heat preservation and thermal conductivity. For example, the insulating layer 13 may be formed of AlN and/or diamond-like carbon (DLC).

In the example embodiments of FIGS. 1 and 2, the amorphous silicon thin film transistor portion may include a bottom-gate structure in which the gate electrode 14, the gate insulating layer 15, the amorphous silicon layer 17, and the source/drain electrodes 18 and 19 may be formed on the insulating layer 13. The gate electrode 14 may be formed in a given region, and the gate insulating layer 15 may be formed on the gate electrode 14 to cover the gate electrode 14.

In the example embodiments of FIGS. 1 and 2, the amorphous silicon layer 17 may be formed on the gate insulating layer 15 to be located at a region including the gate electrode 14. The amorphous silicon layer 17 may include a higher-concentration impurity region which may be formed through a higher-concentration impurity injection. For example, the amorphous silicon layer 17 may include a non-impurity-doped amorphous silicon layer 17b and a heavily impurity-doped amorphous silicon layer 17a, in which a center portion of the amorphous silicon layer 17a corresponding to the gate electrode 14 may be opened.

In the example embodiments of FIGS. 1 and 2, the source/drain electrodes 18 and 19 may be formed to be located on the heavily impurity-doped amorphous silicon layer 17a and the gate insulating layer 15. For example, the source/drain electrodes 18 and 19 may be formed by forming the source/drain electrode material on an entire surface of the substrate 11 and then patterning the source/drain electrode material. In forming the source/drain electrodes 18 and 19, a portion of the heavily impurity-doped amorphous silicon layer 17a may be etched to define a channel region and a source/drain electrode region.

In the example embodiments of FIGS. 1 and 2, a passivation layer 16 may protect the amorphous silicon thin film transistors 10 and 20. In an example, the passivation layer 16 may include an insulating material.

In the example embodiments of FIGS. 1 and 2, if the amorphous silicon thin film transistors 10 and 20 are used as driving transistors for an organic light-emitting display device, the passivation layer 16 may become an interlayer dielectric layer. This passivation layer 16 may be partially etched to form a contact hole for exposing the source/drain electrodes 18 and 19, and electrodes of the organic light-emitting diode may be formed so as to be electrically connected to the source/drain electrodes 18 and 19. Thus, the heat generating portion 12 (e.g., the high resistive layer) may be formed on the substrate 11, the insulating layer 13 may be deposited on the heat generating portion 12, and the amorphous silicon thin film transistor portion may be fabricated on the insulating layer 13.

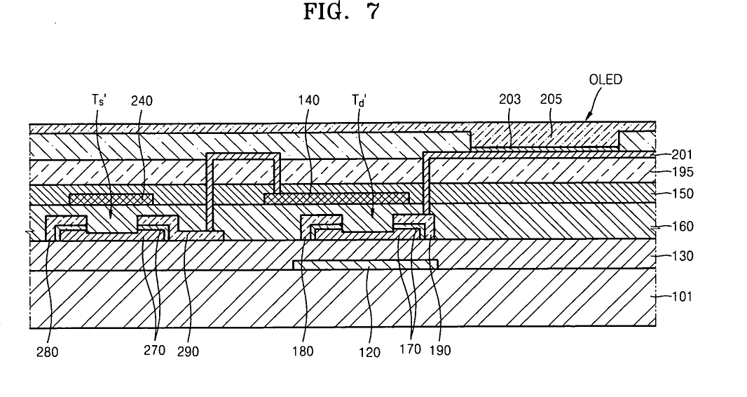

In the example embodiment of FIGS. 1 and 2, the amorphous silicon thin film transistors 10 and 20 may be formed in a bottom-gate structure, and the amorphous silicon thin film transistors 10 and 20 may also be formed in a top-gate structure in which the amorphous silicon layer 17, the source/drain electrodes 18 and 19, the gate insulating layer 15, and the gate electrode 14 are formed on the insulating layer 13. The top-gate structure of an example amorphous silicon thin film transistor will be described later with reference to the example embodiment of FIG. 7 illustrating an organic light-emitting display device.

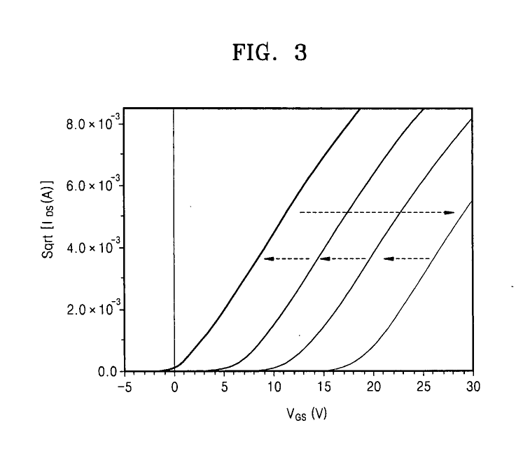

In the example embodiment of FIGS. 1 and 2, in the amorphous silicon thin film transistors 10 and 20, if current is applied to the heat generating portion 12 (e.g., the higher resistive layer), heat may be generated and transferred to the amorphous silicon layer 17. Accordingly, a threshold voltage of the amorphous silicon thin film transistors 10 and 20 may be recovered, as will now be described with reference to FIG. 3.

FIG. 3 is a graph illustrating a change in a threshold voltage dependent on DC current/voltage stress and recovery of the threshold voltage in the amorphous silicon thin film transistors 10 and 20 of FIGS. 1 and 2, respectively, according to another example embodiment of the present invention. In the example embodiment of FIG. 3, an arrow pointing “right” may indicate a change in a threshold voltage due to DC current/voltage stress, and an arrows pointing “left” may indicate a continuous recovery of the threshold voltage through heat application over a given duration.

In the example embodiment of FIG. 3, if the amorphous silicon thin film transistor 10/20 is driven continuously, the threshold voltage may continue to increase in a positive direction due to the DC current/voltage stress. The threshold voltage may be “recovered” (e.g., reset to a default level) by applying, for a given duration, heat to the amorphous silicon layer 17 of the amorphous silicon thin film transistor 10/20 having an increased threshold voltage.

In the example embodiment of FIG. 3, the amorphous silicon thin film transistor 10/20 including the heat generating portion 12 may be used as a driving transistor for an organic light-emitting display device operating for longer periods of time a threshold voltage may be “reset” or recovered. Accordingly, in an organic light-emitting display device having the amorphous silicon thin film transistor 10/20 as a driving transistor, a degradation of the luminance, due to an increase in the threshold voltage of the driving transistor of the organic light-emitting display device, may be reduced and a period of operation, or life cycle, may be increased.

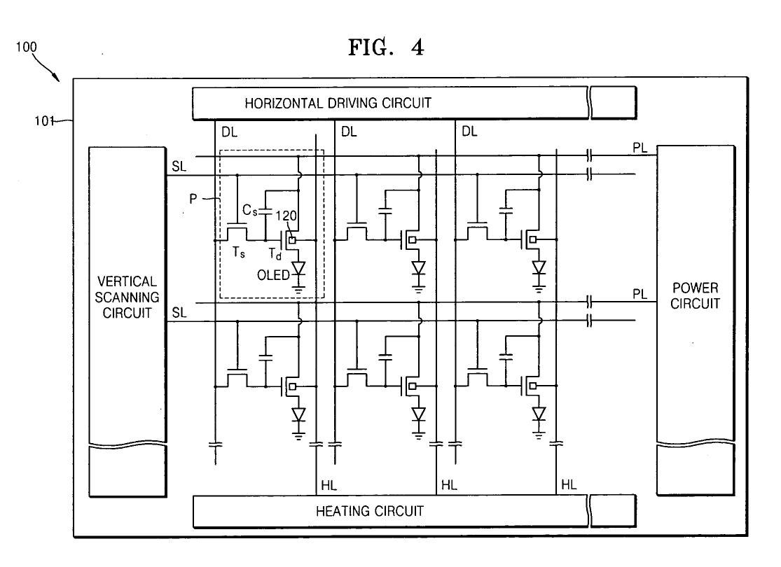

FIG. 4 is an equivalent circuit diagram illustrating a schematic structure of an organic light-emitting display device 100 according to another example embodiment of the present invention.

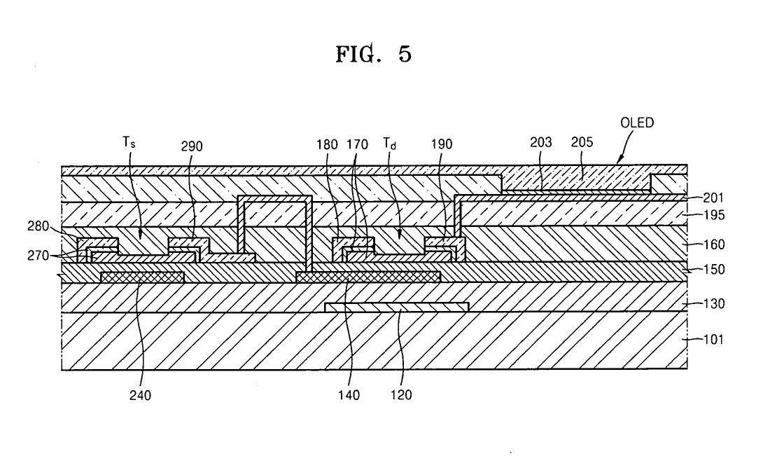

FIG. 5 is a schematic cross-sectional view illustrating a major stacked structure of an organic light-emitting display device according to another example embodiment of the present invention.

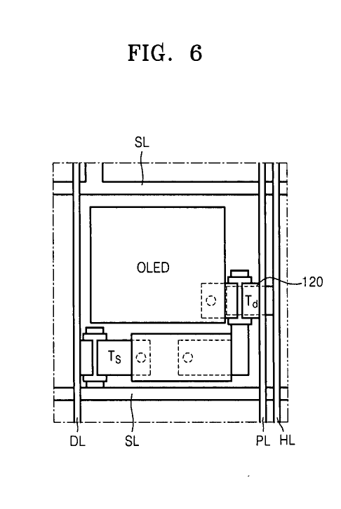

FIG. 6 illustrates a layout of a major structure of one pixel in an organic light-emitting display device according to another example embodiment of the present invention.

In the example embodiment of FIG. 4, the organic light-emitting display device 100 may include a substrate 101, and a plurality of pixels P arranged in a matrix form on the substrate 101, each including a switching transistor, a driving transistor Td, and an organic light-emitting diode (OLED). Each of the pixels may include a heat generating portion 120 positioned under the driving transistor Td. In FIG. 4, the driving transistor Td and the heat generating portion 120 are illustrated as separate elements. However, in another example embodiment of the present invention, the heat generating portion 120 may constitute a portion of the driving transistor Td (e.g., as in the previously-described amorphous silicon thin film transistor 10 and 20 of the example embodiments of FIGS. 1 and 2, respectively).

In the example embodiment of FIG. 5, in an example, the substrate 101 may be embodied as a glass substrate or a plastic substrate. An insulating layer 130 may be further provided on the substrate 101. In an example, the insulating layer 130 may include AlN and/or DLC so as to have increased heat preservation and thermal conductivity.

In the example embodiment of FIG. 5, the heat generating portion 120 may be formed on the substrate 101 at a location corresponding to where the driving transistor Td is formed, and the insulating layer 130 may be formed on the heat generating portion 120 to cover an entire surface of the substrate 101. A selecting and driving element layer may be formed on the insulating layer 130. The selecting and driving element layer may include a switching transistor Ts and the driving transistor Td in a region of each pixel P, which may be a lower-level (e.g., minimum) requirement for implementing a screen. An organic light-emitting diode (OLED) may be formed on the selecting and driving element layer. The organic light-emitting diode may have a structure in which a first electrode, an organic emission layer and a second electrode may be sequentially stacked. As a result, a matrix of the plurality of pixels P may be obtained, each containing the switching transistor Ts, the driving transistor Td and the organic light-emitting diode (OLED).

In the example embodiment of FIG. 5, the driving transistor Td may be an amorphous silicon thin film transistor as described in the example embodiments of FIGS. 1 and 2. In an example, the switching transistor Ts may also be embodied as an amorphous silicon thin film transistor. Alternatively, the switching transistor may be embodied as another type of transistor, such as a polycrystalline thin film transistor.

In the example embodiments of FIGS. 5 and 6, both the driving transistor Td and the switching transistor Ts may be amorphous silicon thin film transistors having a bottom-gate structure. If both the driving transistor Td and the switching transistor Ts are formed of the same type of amorphous silicon thin film transistor 10/20, the driving transistor Td and the switching transistor Ts may each be formed through the same process, thus simplifying a fabricating process.

In the example embodiments of FIGS. 5 and 6, the driving transistor Td and the switching transistor Ts, which may be amorphous silicon thin film transistors, may include gate electrodes 140 and 240, gate insulating layers 150 and 250, amorphous silicon layers 170 and 270 and source/drain electrodes 180, 190, 280 and 290, respectively. The gate electrodes 140 and 240, the gate insulating layers 150 and 250, the amorphous silicon layers 170 and 270, and the source/drain electrodes 180, 190, 280 and 290 may correspond to the gate electrode 14, the gate insulating layer 15, the amorphous silicon layer 17, and the source/drain electrodes 18 and 19 of the amorphous silicon thin film transistors 10 and 20 illustrated in FIGS. 1 and 2, respectively. Accordingly, a further description thereof will be omitted for the sake of brevity.

In the example embodiment of FIGS. 5 and 6, the heat generating portion 120 may be provided to transfer heat to the amorphous silicon layer 170 of the driving transistor Td to recover (e.g., reset) a threshold voltage of the driving transistor Td. The heat generating portion 120 may be patterned to be located in a region between the substrate 101 and the insulating layer 130 corresponding to the amorphous silicon layer 170 of the driving transistor Td. Alternatively, the heat generating portion 120 may be deposited on the entire surface of the substrate 101, between the substrate 101 and the insulating layer 130.

In the example embodiment of FIGS. 5 and 6, the heat generating portion 120 may include a higher resistive layer and/or a lower-power heating element. In an example, the higher resistive layer may generate heat through Joule heating. For example, the higher resistive layer may include indium tin oxide (ITO) and/or indium zinc oxide (IZO). Alternatively, the heat generating portion 120 may any other material capable of effectively generating heat (e.g., any thermally conductive material).

In the example embodiments of FIGS. 5 and 6, a passivation layer 160 may be formed on the driving transistor Td and the switching transistor Ts, and a planarized layer 195 may be formed on the passivation layer 160. The passivation layer 160 may include an insulating material and may function as an interlayer insulating layer.

In the example embodiment of FIGS. 5 and 6, an organic light-emitting diode (OLED) may be formed on the planarized layer 195. The organic light-emitting diode may include a first electrode 201 as an anode, an organic emission layer 203 and a second electrode 205 as a cathode.

In the example embodiments of FIGS. 5 and 6, the drain electrode 290 of the switching transistor Ts and the gate electrode 140 of the driving transistor Td may be electrically connected to each other, and the drain electrode 190 of the driving transistor Td and the first electrode 201 of the organic light-emitting diode (OLED) may be electrically connected to each other. For example, contact holes may be formed in the passivation layer 160 and the planarized layer 195 to reach the drain electrode 290 of the switching transistor Ts and the gate electrode 140 and the drain electrode 190 of the driving transistor Td. Further, during a formation of the first electrode 201 of the organic light-emitting diode (OLED) electrical connection between the drain electrode 290 of the switching transistor Ts and the gate electrode 140 of the driving transistor Td, an electrical connection between the drain electrode 190 of the driving transistor Td and the first electrode 201 of the organic light-emitting diode (OLED) may be formed.

In the example embodiments of FIGS. 4 through 6, in the organic light-emitting display device 100, the source electrode 280 of the switching transistor Ts may be electrically connected to for example a data line DL, to which a data signal from a horizontal driving circuit may be inputted. The data line DL may be electrically connected to the gate electrode 140 of the driving transistor Td via the source/drain electrodes 280 and 290 of the switching transistor Ts. The gate electrode 240 of the switching transistor Ts may be electrically connected to a select line SL, to which a select signal from a vertical scanning circuit may be inputted.

In the example embodiments of FIGS. 4 through 6, the source electrode 180 of the driving transistor Td may be electrically connected to a power supplying line PL, to which driving power from a power supplying circuit is supplied. The power supplying line PL may be connected to the organic light-emitting diode (OLED) via the source/drain electrodes 180 and 190 of the driving transistor Td. The heat generating portion 120 (e.g., a higher resistive layer) may be electrically connected to a Joule heating line HL, to which current from a heating circuit is supplied so that Joule heat may be generated.

In the example embodiments of FIGS. 4 through 6, the data line DL and the select line SL may be arranged to intersect with each other (e.g., at right angles), thereby defining each pixel P. Further, a portion extending from the drain electrode 290 of the switching transistor Ts and the gate electrode 140 of the driving transistor Td, which may be connected to each other, and the power supplying line (PL) may form a storage capacitor Cs in FIG. 4.

In the example embodiments of FIGS. 4 through 6, the heat generating portion 120 (e.g., a higher resistive layer) may be deposited on the entire surface of the substrate 101 or, alternatively, may be patterned to be located locally under the driving transistor Td (e.g., less than all of the surface of the substrate 101), the insulating layer 130 may be deposited, and the selecting and driving element layer having the driving transistor Td and the switching transistor Ts and the organic light-emitting diode (OLED) may be formed on the insulating layer 130, thereby forming the organic light-emitting display device 100.

In the example embodiments of FIGS. 4 through 6, in the organic light-emitting display device 100, the driving transistor Td (e.g., an amorphous silicon transistor) may operate for a relatively long period of time under a substantially constant current stress applied through the power supplying line PL. Current may be supplied from the heating circuit to the heat generating portion 120 through the Joule heating line HL while the organic light-emitting diode (OLED) is turned off or a system including the organic light-emitting display device 100 (e.g., a television (TV), a monitor, or a mobile device) is powered off. Accordingly, heat may be generated from the heat generating portion 120 and transferred to the amorphous silicon layer 170 of the driving transistor Td, thereby recovering (e.g., resetting) a threshold voltage which may have increased during the operation of the driving transistor Td. Further, in the organic light-emitting display device 100, a luminance of the organic light-emitting diode (OLED) may not be degraded life cycle of the OLED may be increased.

FIG. 7 is a schematic cross-sectional view illustrating a major stacked structure of an organic light-emitting display device according to another example embodiment of the present invention.

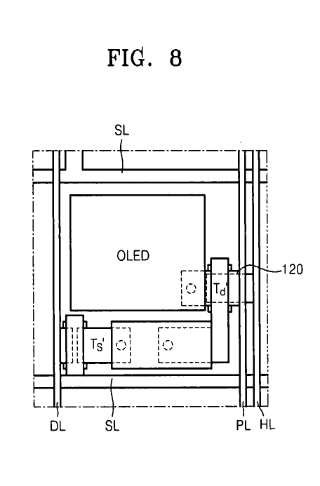

FIG. 8 illustrates a layout of a major structure of one pixel in an organic light-emitting display device according to another example embodiment of the present invention.

In the example embodiments of FIGS. 7 and 8, a further description of like elements above-described and illustrated in FIGS. 5 and 6 has been omitted for the sake of brevity.

In the example embodiments of FIGS. 7 and 8, the organic light-emitting display device 100 may include a driving transistor Td′ and a switching transistor Ts′ having a top-gate structure, in contrast to the driving transistor Td and the switching transistor Ts having a bottom-gate structure as illustrated in FIGS. 5 and 6. The driving transistor Td′ and the switching transistor Ts′ may respectively include, amorphous silicon layers 170 and 270, source/drain electrodes 180 and 190, and 280 and 290, gate insulating layers 150 and 250, and gate electrodes 140 and 240 on the insulating layer 130. A passivation layer 160 may be formed to cover the gate electrodes 140 and 240, and a planarized layer 195 may be formed on the passivation layer 160. An organic light-emitting diode (OLED) may be formed on the planarized layer 195 to be electrically connected to the drain electrode 190 of the driving transistor Td′.

While example embodiments of the present invention have been above described with respect to the amorphous silicon thin film transistors 10 and 20 and the organic light-emitting display device 100 including the heat generating portion 120, (e.g., a higher resistive layer positioned between the substrate 101 and the insulating layer 130), it is understood that the location of the heat generating portion 120 may be adapted so long as the heat generating portion may provide heat to the amorphous silicon layer of the amorphous silicon transistor and/or the driving transistor including the amorphous silicon transistor, each of which potentially having an increased threshold voltage which may be recovered or reset (e.g., reduced) through the application of heat.

Another example embodiment of the present invention is directed to recovering or resetting a threshold voltage of an amorphous silicon thin film transistor through heat application using a heat generating portion. Thus, the amorphous silicon thin film transistor may be employed as a driving transistor for an organic light-emitting display device and may have a longer period of operation (e.g., because the amorphous silicon thin film transistor may have a reset-capable threshold voltage to increase a period of operation). Thus, a luminance degradation, which is conventionally associated with increased threshold voltages of the driving transistor, may be reduced and/or avoided, increasing a potential operating period for an OLED.

Example embodiments of the present invention being thus described, it will be obvious that the same may be varied in many ways. For example, while above-described example embodiments of the present invention are directed to OLEDs, it is understood that other example embodiments of the present invention may be applied to a driving transistor for any type of display device (e.g., LCDs, Plasma displays, etc.).

Such variations are not to be regarded as a departure from the spirit and scope of example embodiments of the present invention, and all such modifications as would be obvious to one skilled in the art are intended to be included within the scope of the following claims.

What is claimed is:

1. An amorphous silicon thin film transistor, comprising:
an amorphous silicon thin film transistor portion including a gate electrode, a gate insulating layer, an amorphous silicon layer, and source/drain electrodes; and
a heat generating portion generating heat and applying the heat to the amorphous silicon layer to reduce a threshold voltage of the amorphous silicon thin film transistor portion.

2. The amorphous silicon thin film transistor of claim 1, wherein each of the gate electrode, gate insulating layer, amorphous silicon layer and source/drain electrodes are formed on a substrate.

3. The amorphous silicon thin film transistor of claim 2, further comprising:
an insulating layer positioned between the substrate and the amorphous silicon thin film transistor portion,
wherein the heat generating portion is formed at least within a region between the substrate and the insulating layer.

4. The amorphous silicon thin film transistor of claim 3, wherein the heat generating portion is positioned so as to at least overlap with the amorphous silicon layer.

5. The amorphous silicon thin film transistor of claim 3, wherein the thin film transistor portion has a bottom-gate structure in which the gate electrode, the gate insulating layer, the amorphous silicon layer, and the source/drain electrodes are sequentially formed on the insulating layer.

6. The amorphous silicon thin film transistor of claim 5, wherein the amorphous silicon layer includes a higher-concentration impurity region that is formed through higher-concentration impurity injection, and the source/drain electrodes are formed on the higher-concentration impurity region of the amorphous silicon layer.

7. The amorphous silicon thin film transistor of claim 3, wherein the amorphous thin film transistor portion has a top-gate structure in which the amorphous silicon layer, the source/drain electrodes, the gate insulating layer, and the gate electrode are sequentially formed on the insulating layer.

8. The amorphous silicon thin film transistor of claim 7, wherein the amorphous silicon layer includes a higher-concentration impurity region that is formed through a higher-concentration impurity injection, and the source/drain electrodes are formed on the higher-concentration impurity region of the amorphous silicon layer.

9. The amorphous silicon thin film transistor of claim 1, wherein the heat generating portion includes a higher resistive layer generating heat through Joule heating.

10. The amorphous silicon thin film transistor of claim 9, wherein the higher resistive layer is formed so as to either overlap with one of (i) an entirety of a substrate upon which the amorphous silicon thin film transistor portion is formed and (ii) at least with a portion of the substrate corresponding to the amorphous silicon layer of the amorphous silicon thin film transistor.

11. The amorphous silicon thin film transistor of claim 10, wherein the higher resistive layer includes at least one of indium tin oxide (ITO) and indium zinc oxide (IZO).

12. An organic light-emitting display device comprising:
a substrate; and
a plurality of pixels arranged in a matrix form on the substrate, each of the pixels comprising a switching transistor, a driving transistor, and an organic light-emitting diode,
wherein the driving transistor is embodied as the amorphous silicon thin film transistor of claim 1.

13. The organic light-emitting display device of claim 12, wherein the switching transistor is structurally embodied in the same manner as the driving transistor.

14. The organic light-emitting display device of claim 12, wherein the heat generating portion includes a higher resistive layer generating heat through Joule heating.

15. The organic light-emitting display device of claim 14, further comprising:
a select line electrically connected to a gate electrode of the switching transistor;
a data line electrically connected to the gate electrode of the driving transistor through source/drain electrodes of the switching transistor;
a power supplying line connected to the organic light-emitting diode through the source/drain electrodes of the driving transistor; and
a Joule heating line electrically connected to the heat generating portion, wherein current is applied to the heat generating portion through the Joule heating line if the organic light-emitting diode is turned off or if a system including the organic light-emitting display device is powered off, and heat is generated by the heat generating portion and transferred to the amorphous silicon layer of the driving transistor, to reduce the threshold voltage of the amorphous silicon thin film transistor portion.

16. The organic light-emitting display device of claim 12, further comprising:
a select line electrically connected to a gate electrode of the switching transistor;
a data line electrically connected to the gate electrode of the driving transistor through source/drain electrodes of the switching transistor;
a power supplying line connected to the organic light-emitting diode through the source/drain electrodes of the driving transistor; and
a Joule heating line electrically connected to the heat generating portion, wherein current is applied to the heat generating portion through the Joule heating line if the organic light-emitting diode is turned off or if a system including the organic light-emitting display device is powered off, and heat is generated by the heat generating portion and transferred to the amorphous silicon layer of the driving transistor, to reduce the threshold voltage of the amorphous silicon thin film transistor portion.

17. A method of reducing a threshold voltage, comprising:
applying heat to an amorphous silicon layer if a threshold voltage of an amorphous silicon thin film transistor rises above a default level, the amorphous silicon thin film transistor including the amorphous silicon layer, the applied heat configured to reset the threshold voltage to the default level.

18. The method of claim 17, wherein the applied heat is generated in a heat generating portion with a Joule heating process.
